(19) United States
(12) Patent Application Publication
(10) Pub. No.: US 2010/0243063 A1
(43) Pub. Date: Sep. 30, 2010

(54) VAPOUR DELIVERY SYSTEM

(76) Inventor: Malcom Woodcock, Oxford (GB)

Correspondence Address: William H Bollman Manelli Denison & Selter, 2000 M Street NW 7th Floor, Washington, DC, 20036, US

(21) Appl. No.: 12/733,791

(22) PCT Filed: Sep. 25, 2008
(86) PCT No.: PCT/GB2008/003271

§ 371 Date: Mar. 19, 2010

(30) Foreign Application Priority Data
Sep. 25, 2007 (GB) 0718801.4

(51) Int. Cl. F15D 1/00; C23C 16/453

(52) U.S. Cl. 137/1; 137/571; 118/715; 118/620

(57) ABSTRACT

A delivery system (10) for delivering species to a processing chamber (14) for imparting a desired surface property to one or more large items—such as shoes—comprises: a first container (16) for filling with liquid species; a second container (18) for receiving liquid species from the first container (16); a first flow control means (20) for controlling a volume of liquid species which is allowed to flow from the first container to the second container (18); evaporation means (30) for evaporating liquid species in the second container; and a second flow control means (38) for controlling flow of evaporated species from the second container (18) to a processing chamber (14).

### FIELD OF THE INVENTION

This invention relates to a delivery system for delivering species to a processing chamber, a method of operating same, and to apparatus for plasma processing of a surface of an article comprising such a delivery system.

### BACKGROUND OF THE INVENTION

Delivery systems are hereto known for delivering and metering vapour from a high boiling-point liquid into a vacuum chamber, in order to carry out a chemical or physical process within the vacuum chamber. Such systems are not well suited to the case in which the liquid is a chemically reactive monomer.

In a known bubbler system, carrier gas bubbles through the liquid, absorbing and transporting the vapour into the vacuum chamber. In a known evaporator system, a sufficiently high vapour pressure is generated (of the order of 1 Torr) to deliver the vapour via a mass flow controller into the vacuum chamber. In a vapour delivery system, liquid is heated and drawn through a fine orifice, typically assisted by a carrier gas.

Bubbler and vapour delivery systems suffer from the disadvantage that a flow of carrier gas is required, and therefore restrictions are placed on the available range of vapour/carrier composition. Evaporator systems have the drawback that the liquid must be heated to a sufficiently high temperature that it generates a high enough pressure to enable a mass flow controller to function, with attendant risks of instability, including the risk of polymerisation in the case that the liquid is a monomer. Vapour delivery systems are also prone to blockage of the fine orifice, either by particulate contamination in the liquid or as a result of a tendency to polymerise, in the case that the liquid is a monomer.

### PRIOR ART

European Patent Application Number EP-A3-1 202 321 (Applied Materials Inc) describes an apparatus and method for vaporising and delivering a liquid precursor to a processing chamber. An example of liquid precursor is trimethylsilane (TMS) which is employed in so-called plasma enhanced chemical vapour deposition (PECVD) processes for example as employed in the manufacture of large scale integrated circuits.

A problem suffered in the fabrication plant, where PECVD processes are present is that the TMS sometimes has to be transported from an evaporation chamber some considerable distance from a reaction chamber and this produces an inconsistent precursor flow rate. The apparatus disclosed overcomes this problem by locating an ampoule adjacent a reaction chamber and vaporising a liquid precursor in close proximity thereto.

European Patent Application Number EP-A1-0 548 944 (Canon KK) describes a gas feed apparatus for us with a chemical vapour deposition system that forms stable films despite fluctuations to operational parameters.

A further example of a liquid precursor refill system is described in International Patent Application number WO-A1-2006/059187 (L'Air Liquide SA). The liquid precursor system includes a remote heater and a delivery line that delivers vapour to a reaction chamber. The system described overcomes the problem of having large volumes of reactive, such as pyrophoric, or expensive material stored in long transit lines.

US Patent Application US 2003/0217697 (Hideaki Miyamoto et al) discloses a liquid evaporator for supplying a gas to a discharge tank, for example of the type used in semiconductor manufacture. The system utilises a complex array of temperature controlled valves in order to compensate for heat losses in the evaporated liquid that occur due to adiabatic expansion.

The aforementioned disclosures describe solutions to well known problems associated with the fabrication of semiconductors and other similar devices, such as very large scale integrated (VLSI) circuits. None of the systems is suitable for use in a system for coating larger items, such as, for example, household items, and items of clothing or footwear, paper goods or consumer products such as electronic items.

No mention is made in any of the aforementioned documents of a solution to the problem associated with coating a large item with a material so as to impart specific properties to the surface thereof.

An object of the present invention is to provide an apparatus for delivering a species to a chamber for the purposes of imparting specific properties to large items in the chamber or passing therethrough.

The term large item is intended to include such things as, for example: sports equipment, fabrics and similar, materials, paper products and synthetic plastics goods, clothing, high value fashion items and accessories, footwear, electrical goods, personal electronic devices, mobile telephones, pagers, personal digital assistants (PDAs) and MP3 devices.

### SUMMARY OF THE INVENTION

According to the present invention there is provided a delivery system for delivering species to a processing chamber, within which, in use, at least one large item is located for the purposes of having one or more properties imparted to the surface(s) thereof, the system comprising:

a first container for filling with liquid species;

a second container for receiving liquid species from said first container;

a first flow control means for controlling a volume of liquid species which is allowed to flow from said first container to said second container;

evaporation means for evaporating liquid species in said second container; and

a second flow control means for controlling flow of evaporated species from said second container to a processing chamber.

The present invention also provides a method of operating a delivery system for delivering species to a processing chamber, within which, in use, at least one large item is located for the purposes of having one or more properties imparted to the surface(s) thereof, the system comprising:

a first container for filling with liquid species;

a second container for receiving liquid species from said first container;

a first flow control means for controlling a volume of liquid species which is allowed to flow from said first container to said second container;

evaporation means for evaporating liquid species in said second container; and

a second flow control means for controlling flow of evaporated species from said second container to a processing chamber;

wherein the method comprises:

allowing said volume of liquid species to flow from said first container to said second container;

evaporating liquid species in said container; and

allowing said evaporated species to flow into said processing chamber.

The present invention further provides apparatus for plasma processing of a surface of an article, the apparatus comprising:

a processing chamber into which an article can be placed;

a delivery system as claimed in claim 1, hereinafter for delivering a species to the processing chamber for forming a plasma in said chamber;

means for generating an electrical field internally of the processing chamber for forming a plasma when said species is supplied thereto so that a surface of said article can be processed; and

a pressure control means for selectively controlling pressure in the processing chamber.

Other preferred and/or optional features of the invention are defined in the accompanying claims.

The invention will now be described, by way of example only, with reference to the accompanying drawings, in which:—

### BRIEF DESCRIPTION OF THE DRAWINGS

FIG. 1 is a schematic representation of a delivery system for delivering species to a processing chamber; and

FIG. 2 is a table showing states of operation of the delivery system of FIG. 1.

### DETAILED DESCRIPTION OF THE ILLUSTRATED EMBODIMENTS

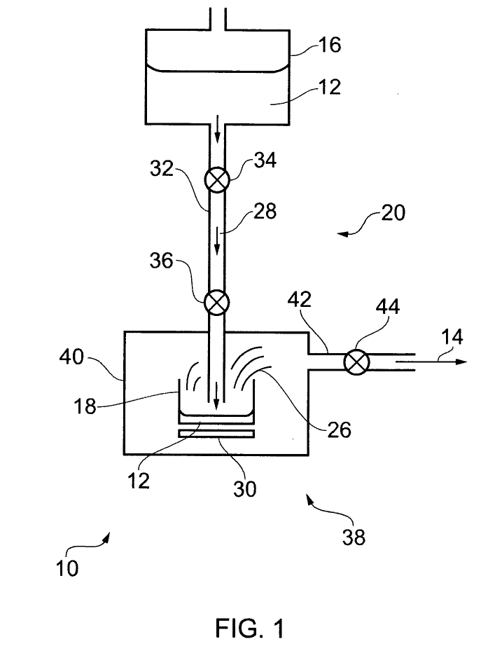

Referring to FIG. 1, a delivery system 10 is shown for delivering species to a processing chamber 14. The system 10 comprises a first container 16 which can be filled with liquid species 12; a second container 18 for receiving liquid species from first container 16; a first flow control means 20 for controlling a volume of liquid species which is allowed to flow from the first container to the second container; evaporation means 30 for evaporating liquid species in the second container; and a second flow control means 38 for controlling flow of evaporated species 26 from the second container to the processing chamber 14.

The first container 16 can be filled manually by a system operator and can take the form of a hopper or a closed container with an inlet. The second container 18 may be a flask or beaker, or other vessel for containing liquid to be evaporated and is preferably open to facilitate the supply of liquid to the container and the evaporation of liquid from the container.

Evaporation means 30 is provided for evaporating the liquid species when it is in the container 18. The liquid species in the container can be heated as shown in FIG. 1 to promote evaporation, and such heating means may comprise a heated plate or if the container is conductive, by induction of heat in the container.

The heat required to achieve required evaporation is a function of a number of different factors. These factors include pressure in the surrounding region above the liquid, and the concentration of species and other constituents in the region; temperature of the liquid; inter-molecular forces in the liquid; and surface area of the liquid. The inter-molecular forces in the liquid are constant for each species and the surface area is constant for a selected container of a particular size and shape. The pressure required for a given processing step is also generally constant, although subject to some fluctuation. Therefore, the amount of heat provided to the liquid species in order to achieve a required flow of species into the processing chamber can be determined either by calculation or by experimentation. Such a predetermined characteristic response of the species to activation of the evaporation means can be determined for a plurality of species and for a plurality of processing steps to be conducted in the processing chamber and the evaporation means can be controlled to achieve the required rate of evaporation.

The first flow control means 20 has an internal space 28 sized to receive a predetermined volume of liquid species when filled from the first container 16. The first flow control means can control flow of liquid species into the internal space 28 and flow of liquid species from the internal space to said second container 18.

More particularly, the first flow control means 20 comprises a conduit 32 and first valve 34 at an upstream portion of the conduit and a second valve 36 at a downstream portion of the conduit. The internal space is defined by the conduit, and the first and the second valves. The internal space 28 occupies a portion of the free space inside each of the valves in addition to the space inside the conduit, and such free space is taken into account when determining the volume of the internal space 28.

The first valve 34 can be opened to allow liquid species to flow into the internal space 28. The second valve 36 can be opened to allow liquid species to flow from the internal space 28 to the second container 18. The first valve 34 can be opened and the second valve 36 can be closed to allow liquid species to fill the internal space 28. When the internal space is filled the first valve 34 can be closed and the second valve 36 can be opened to allow a predetermined volume of liquid species, contained in the internal space 28, to flow into the second container 18.

The predetermined volume of liquid species can be readily changed as required by selection of any one of a plurality of conduits with different internal volumes. Different processing steps to be performed in the processing chamber 14 require different flow rates through the chamber and concentrations of evaporated species. The internal volume of conduit 32 can be selected according to a required processing step to be performed in the chamber 14.

The second flow control means 38 as shown in FIG. 1 comprises an evaporation chamber 40 into which species can be evaporated from container 18 and a conduit 42 leading from the evaporation chamber 40 towards the processing chamber 14. The conduit 42 comprises a valve 44 for controlling flow of evaporated species 26 from the second container 18 to the processing chamber 14. Evaporation chamber 40 and conduit 42 may comprise additional heating means (not shown) for reducing condensation of species which has been evaporated from the container 18 when it contacts an internal surface of the evaporation chamber and the conduit.

The delivery system may form part of apparatus for plasma processing of a surface of an article. Such an apparatus typically comprises a processing chamber into which an article can be placed; a delivery system as described herein for delivering an species to the processing chamber for forming a plasma in the chamber; means for generated an electrical field internally of the processing chamber for forming a plasma when said species is supplied thereto so that a surface of said article can be processed; and pressure control means for selectively controlling pressure in the processing chamber.

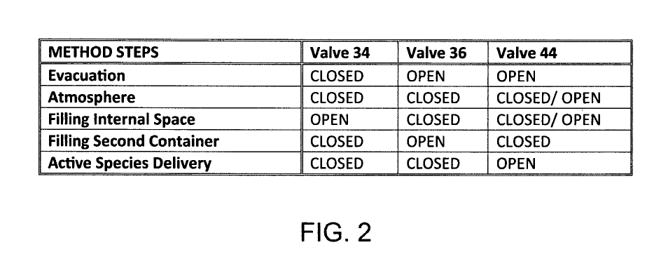

A method of operating delivery system 10 will now be described with reference to FIGS. 1 and 2. In FIG. 2, references are provided to valve 34, valve 36 and valve 44. References in the table to “Open” are to a valve being open to the extent that the valve is open sufficient to allow required flow of species therethrough. References to “Closed” are to a valve being closed to restrict or prevent the flow of species therethrough.

The first container 16 is typically filled with an amount of liquid species for delivery of species to the processing chamber sufficient for a multiplicity of processing steps.

Valve 34 is closed and valves 36 and 44 are opened. A pressure control means of a processing apparatus evacuates the processing chamber and the delivery system downstream of valve 34 to typical pressures in the region of several mTorr. Evacuation of the delivery system in this way clears blockages.

Next, valves 34, 36 are closed and valve 44 may be opened or closed whilst the delivery system is vented to atmosphere.

Next, valve 34 is opened and valve 36 is closed. Valve 44 may be opened or closed as it is not important in this process step. Liquid species is allowed to flow under gravity (or other means of inducing flow) from the first container 16 through valve 34 and into conduit 32. Valve 36 which is closed restricts further flow of the species towards the second container 18 so that the internal space 28 of the first flow control means 20 can be filled.

When the internal space 28 is filled, valve 34 is closed thereby enclosing a predetermined volume of liquid species in the internal space 28. Valve 36 is opened to allow the predetermined volume of liquid to flow into the second container 18. Valve 44 may be opened or closed during this stage. Advantageously, valve 44 is closed to isolate the delivery system from the processing chamber so that species can be delivered to the processing chamber on command when valve 44 is opened. If valve 44 is opened during filling of the second container 18, some liquid species may evaporate and enter processing chamber 14 before it is required for processing.

When the second container 18 has received the predetermined volume of liquid, evaporation means 30 is activated to evaporate liquid species in the second container 18. Valve 44 is closed and valve 36 may also be closed to prevent evaporated species travelling into the first flow control means 20.

When evaporated species 26 is required for plasma processing, valve 44 is opened and vapour is drawn into the processing chamber 14 by the pressure gradient generated by the pressure control means of the plasma processing apparatus.

The volume of liquid species supplied to the second container 18 as described above is predetermined as required for a particular process step or particular process steps to be performed in the process chamber. When processing has been performed valve 36 is opened and the pressure control means evacuates the system 10 as described in the first method step above.

Such a method as described herein may be controlled by control means in operative connection with valves 34, 36 and 44, and with evaporation means 30. Such a control means may comprise a processor unit for controlling operation of the valves and the evacuation means, and a memory in which for instance the table shown in FIG. 2 is stored.

In addition to those features described above and shown in FIG. 1, the system 10 may suitably comprise monitoring means (not shown) for measuring a rate over time of evaporation of species from the second container 18 so that flow of evaporated species delivered to the processing chamber 14 can be monitored. The monitoring means may comprise means for measuring a change in weight (or mass) of liquid species in said container over time. A change in weight is a measure of the weight or mass of species which has been evaporated from container 18 and delivered to the processing chamber. Suitable weighing means includes a load cell, balance or a strain gauge. An example of a liquid species is ‘PFAC 8’ or any perfluorinated chemical with an active end or side group and when evaporated onto a surface of a material—such as a woven fabric—this will impart water repellent properties to the material. This is highly desirable when wanting to manufacture water repellent clothes or items of footwear.

Alternatively or additionally, the monitoring means may comprise a level sensor for sensing a level of species in the container, such as an ultrasonic, optical or capacitive sensor.

A change in weight of liquid species during a delivery cycle is indicative of the flow of evaporated species delivered to the processing chamber. It can therefore be determined by measuring such a change of weight if a correct flow of evaporated species has entered the processing chamber. If a correct flow is determined to have entered the processing chamber then, it can also be determined that processing has been carried out successfully. If an incorrect flow is determined to have entered the processing chamber then, it can be determined that processing has been carried out unsuccessfully, or not to the standard required.

A determination of successful or unsuccessful processing can be made by a comparison between the expected change in weight for a delivery and the real time monitored change in weight. If the monitoring means has a display showing weight, then such a determination can be made simply by manually comparing a monitored change of weight with a look up table.

The invention has been described by way of three embodiments, with modifications and alternatives, but having read and understood this description further embodiments and modifications will be apparent to those skilled in the art. All such embodiments and modifications are intended to fall within the scope of the present invention as defined in the accompanying claims.

1. A delivery system for delivering species to a processing chamber, within which, in use, at least one large item is located for the purposes of having one or more properties imparted to the surface(s) thereof, the system comprising:
a first container for filling with liquid species;
a second container for receiving liquid species from said first container;
a first flow control means for controlling a volume of liquid species which is allowed to flow from said first container to said second container;
evaporation means for evaporating liquid species in said second container; and
a second flow control means for controlling flow of evaporated species from said second container to a processing chamber.

2. A delivery system as claimed in claim 1, wherein said first flow control means has an internal space sized to receive a predetermined volume of liquid species when filled from said first container and wherein said first flow control means can control flow of liquid species into said internal space and flow of liquid species from said internal space to said second container.

3. A delivery system as claimed in claim 1, wherein said first flow control means comprises a conduit and a first valve at an upstream portion of said conduit and a second valve at a downstream portion of said conduit, and said internal space is defined by said conduit and said first and said second valves.

4. A delivery system as claimed in claim 3, wherein said first valve can be opened to allow liquid species to flow into said internal space.

5. A delivery system as claimed in claim 3, wherein said second valve can be opened to allow liquid species to flow from said internal space to said second container.

6. A delivery system as claimed in claim 4, wherein said first valve can be opened and said second valve can be closed to allow liquid species to fill said internal space.

7. A delivery system as claimed in claim 6, wherein when the internal space is filled said first valve can be closed and said second valve can be opened to allow said predetermined volume of liquid species to flow into said second container.

8. A delivery system as claimed in claim 1, wherein said second flow control means comprises a valve which can be opened to allow evaporated species to flow into a processing chamber and can be closed to restrict flow into said processing chamber.

9. A method of operating a delivery system for delivering species to a processing chamber, said system comprising:
a first container for filling with liquid species;
a second container for receiving liquid species from said first container;
a first flow control means for controlling a volume of liquid species which is allowed to flow from said first container to said second container;
evaporation means for evaporating liquid species in said second container; and
a second flow control means for controlling flow of evaporated species from said second container to a processing chamber;
wherein the method comprises:
allowing said volume of liquid species to flow from said first container to said second container;
evaporating liquid species in said container; and
allowing said evaporated species to flow into said processing chamber.

10. A method as claimed in claim 9, wherein said first flow control means comprises a conduit and first valve upstream of said conduit and a second valve downstream of said conduit, and an internal space of predetermined volume is defined by said conduit and said first and said second valves, and wherein said first valve is opened and said second valve is closed to allow liquid species to flow into said internal space, and said first valve is closed and said second valve is opened to allow said predetermined volume of liquid to flow into said second container.

11. A method as claimed in claim 10, wherein said second flow control means comprises a valve which can be opened to allow evaporated species to flow into a processing chamber and can be closed to restrict flow into said processing chamber.

12. A system as claimed in claim 1, wherein the species is a monomer for use in plasma processing

13. Apparatus for plasma processing of a surface of an article, the apparatus comprising:
a processing chamber into which an article can be placed;
a delivery system as claimed in claim 1 for delivering a species to the processing chamber for forming a plasma in said chamber;
means for generated an electrical field internally of the processing chamber for forming a plasma when said species is supplied thereto so that a surface of said article can be processed; and
pressure control means for selectively controlling pressure in the processing chamber.
